(19) United States
(12) Patent Application Publication
(10) Pub. No.: US 2018/0175885 A1
(43) Pub. Date: Jun. 21, 2018

(54) Hybrid LDPC-SEC/SECDED Decoding

(71) Applicant: Toshiba Memory Corporation, Tokyo (JP)

(72) Inventors: Paul Hanham, Didcot (GB); Josh Bowman, Didcot (GB); David Symons, Kidlington (GB)

(21) Appl. No.: 15/383,569

(22) Filed: Dec. 19, 2016

(51) Int. Cl. H03M 13/11; G06F 11/10; G11C 29/52; H03M 13/15; H03M 13/29; G06F 3/06

(52) U.S. Cl. CPC H03M 13/1108; G06F 11/1068; G11C 29/52; H03M 13/1111; G06F 3/0679; H03M 13/152; H03M 13/2927; G06F 3/0619; G06F 3/064; H03M 13/1174

(57) ABSTRACT

A solid state storage device, comprising a non-volatile memory configured to store data encoded into a plurality of encoded data groups, each encoded data group of the plurality being encoded using a BCH or Hamming parity scheme, the plurality of encoded data groups being collectively further encoded by a parity scheme using a Low Density Parity Check (LDPC) code, a non-volatile memory controller communicatively coupled to the non-volatile memory and configured to access the plurality of encoded data groups, a first decoder configured to first decode the plurality of encoded data groups by hard-decision decoding the parity in each encoded data group, and a second decoder commutatively coupled to the first decoder and configured to determine the data groups decoded by the first decoder that contain errors, and to decode the parity of the data groups that contain errors using likelihood-of-errors information that is input to the second decoder.

### FIELD OF THE INVENTION

The present disclosure relates to solid state storage devices and methods that increase the efficiency in decoding hard-encoded Low Density Parity Check (LDPC) encoded data, so as to reduce the power consumed by the solid state storage device during such decoding.

### BACKGROUND OF THE INVENTION

Error correcting schemes for solid state memory devices have been the subject of many studies in the recent years, particularly in respect of LDPC codes which are based on iterative probability based calculations that converge. LDPC codes, also known as soft-decision schemes, have shown good decoding performance compared to other error-correcting schemes such as turbo codes, approaching within 0.0045 dB of the Shannon limit of maximum possible efficiency of error-correcting schemes. Various algorithms are employed to implement LDPC decoding, based upon using iterations to approximate a maximum likelihood solution, but there may be no limit to the number of iterations as the convergence to a solution is asymptotic. This lack of a defined maximum is problematic, particularly when extremely low error rates are required (as is the case for flash memory applications).

Other error correction schemes such as Bose Chaudhuri Hocquengheim (BCH) codes and Reed-Solomon (RS) codes are based on algebraic formulation and/or algebraic codes. The ability of these hard-decision schemes to reliably correct a certain number of errors or less has been mathematically demonstrated, however they require increased computational support as the number of correctable bit errors increases.

In order to maximize the benefits of both the soft-decision and the hard-decision error correction schemes, concatenated correction codes have been developed and used in correction schemes that employ both an LDPC code and a BCH code, where the BCH code is used as an outer code and the LDPC code is used as an inner code, for example. However such concatenated schemes still invariably rely on the use of the iterative probabilistic process of the LDPC code, which carries with it the weight of increased decoding processing time and power consumption as the length of the code word increases. This is primarily due to the sequential decoder processing of the inner LDPC code followed by the processing of the outer BCH code.

### BRIEF DESCRIPTION OF THE INVENTION

According to one implementation of the present disclosure, there is provided a storage device comprising a non-volatile memory configured to store data encoded into a plurality of encoded data groups, each encoded data group of the plurality being encoded using a BCH or SECDED parity scheme, the plurality of encoded data groups being collectively further encoded by a parity scheme using a Low Density Parity Check (LDPC) code; a non-volatile memory controller communicatively coupled to the non-volatile memory and configured to access the plurality of encoded data groups; a first decoder configured to decode the plurality of encoded data groups by decoding the parity in each encoded data group; and a second hybrid decoder commutatively coupled to the first decoder and configured to determine the data groups decoded by the first decoder that likely contain errors and the data groups decoded by the first decoder that do not contain errors, and to decode the parity of the data groups decoded by the first decoder using the likelihood of errors as log likelihood ratio (LLR) information input to the second hybrid decoder.

In certain implementations, the second decoder is further configured to detect the data groups decoded by the second decoder that were initially determined not to likely contain an error but may in fact contain an error, and decode the parity in those data groups and the data groups that contain errors in order to make a final check for correctness of decoding. In some implementations, the likelihood-of-errors information is the log likelihood ratio (LLR).

In other implementations, the second decoder further includes a sub-decoder to decode the parity of the data groups decoded by the first decoder that contain errors. In some implementations, the sub-decoder is a hard-decision BCH decoder or a soft-decision Hamming code decoder. In further implementations, the parity decoded by the first decoder is based on a BCH code or a Hamming code. According to some implementations, the parity scheme is a single-error correcting (SEC) code or a single-error correcting double-error detecting (SECDED) code. In other implementations, SEC or SECDED decoded data with one error is fixed by the second decoder.

In further implementations, the second decoder decodes the parity of the decoded data groups iteratively using soft-decision decoding. In some implementations, the second decoder independently uses log likelihood ratio (LLR) information as soft information in each iteration of decoding the parity. According to an implementation, the second decoder independently uses log likelihood ratio (LLR) information as soft information to determine the data groups decoded by the first decoder that do not contain errors. In some implementations, the log likelihood information is used by a soft-decision Hamming decoder to decode the parity of the data groups that contain errors.

According to one implementation of the present disclosure, there is provided a method of decoding non-volatile memory of a memory system, the method comprising: accessing, by a non-volatile memory controller, data stored in the non-volatile memory, the data encoded into a plurality of encoded data groups, each data group of the plurality being encoded using a hard-decision parity scheme, and the plurality being further encoded by a soft-decision parity scheme using a Low Density Parity Check (LDPC) code; hard decision decoding, by a first decoder, the parity in each encoded data group; determining, by a second decoder, the data groups decoded by the first decoder that contain errors and the data groups decoded by the first decoder that likely do not contain errors; and decoding, by the second decoder, the decision parity of the data groups decoded by the first decoder that contain errors using likelihood-of-errors information that is input to the second decoder.

In some implementations, the method further comprises detecting, by the second decoder, the data groups decoded by the second decoder that were initially determined not to likely contain an error but may in fact contain an error, and decoding, by the second decoder, the parity in those data groups and the data groups that contain errors in order to make a final check for correctness of decoding. In other implementations, the likelihood-of-errors information is the log likelihood ratio (LLR). In further implementations, the method further comprises decoding, by a sub-decoder, the parity of the data groups decoded by the first decoder that contain errors. In some implementations, the sub-decoder is a hard-decision BCH decoder or a soft-decision Hamming code decoder.

In certain implementations, the parity decoded by the first decoder is a BCH code or a Hamming code. In other implementations, the hard-decision parity scheme is a single-error correcting (SEC) code or a single-error correcting double-error detecting (SECDED) code. In some implementations, SEC or SECDED decoded data with one error is fixed by the second decoder. In some implementations, the second decoder decodes the parity of the decoded data groups iteratively using soft-decision decoding. In certain other implementations, the second decoder independently uses log likelihood ratio (LLR) information as soft information in each iteration of decoding the parity. According to some implementations, the second decoder independently uses log likelihood ratio (LLR) information as soft information to determine the data groups decoded by the first decoder that do not contain errors. In other implementations, the log likelihood information is used by a soft-decision Hamming decoder to decode the parity of the data groups that contain errors.

### BRIEF DESCRIPTION OF THE FIGURES

The foregoing and other objects and advantages will be apparent upon consideration of the following detailed description, taken in conjunction with the accompanying drawings, in which like reference characters refer to like parts throughout, and in which:

FIGS. 1A and 1B illustrate communication between variable and check nodes representative of iterative decoding in an LDPC code;

FIGS. 2A and 2B illustrate a Tanner graph for decoding an LDPC code;

FIG. 3 shows the structure of concatenated encoding scheme for data using BCH and LDPC according to the prior art;

FIG. 4 shows the structure of the hybrid BCH and LDPC encoded data according to an implementation of the present invention;

FIG. 5 is a block diagram of a system for separate hard decision BCH and soft decision LDPC decoding according to the prior art;

FIG. 6 is a block diagram of a system for integrated hard and soft decision BCH/Hamming and soft decision LDPC decoding according to an implementation of the present invention;

FIG. 7 is a representative process flow of the hybrid decoding process according to an implementation of the present invention;

FIG. 8 shows a hybrid hard-LDPC decoding calculated on a variable node group basis according to an implementation of the present invention; and

### DETAILED DESCRIPTION OF THE INVENTION

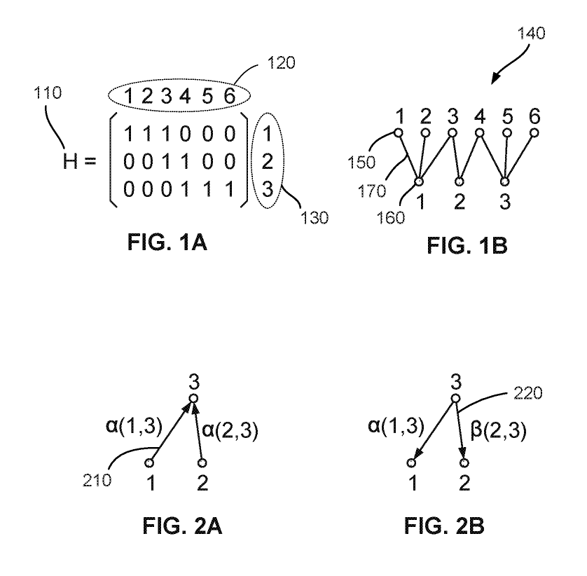

In order to appreciate the features of the present disclosure, iterative decoding of a Low-Density Parity Check (LDPC) code will be described with respect to FIGS. 1A and 1B. FIG. 1A illustrates a parity code defined by a (6, 3) parity check matrix H 110. Matrix H has 3 rows and 6 columns, and the elements of H describe the relationship between 6 received symbols 120 (represented by the columns) and 3 parity checks 130 (represented by the rows). The LDPC code can also be described graphically by a Tanner graph 140 as shown in FIG. 1B, which illustrates the (6, 3) LDPC code 110 of FIG. 1A in the form of variable nodes 150 and check nodes 160. The variable nodes 150 correspond to the columns of the matrix H, and the check nodes 160 correspond to the rows of the matrix H. The variable nodes 150 represent the variables or estimations of the decoded message, and the check nodes 160 represent the parity check constraints of the LDPC code. Elements of the matrix H that are non-zero are represented by an edge 170 in the Tanner graph 140.

An LDPC code is decoded by repeatedly updating, at the variable nodes 150 and the check nodes 160, log likelihood ratio (LLR) information associated with the edges of the Tanner graph 140. The LLR compares the ‘goodness of fit’ of the decoding calculations performed at the variable and check nodes 150, 160 that are connected by an edge 170 to determine a bit in question of the decoded data is a ‘1’ or ‘0’. The LLR information contains two types of information: LLR information from a check node 160 to a variable node 170, denoted as 210 in FIG. 2A, and LLR information from a variable node 170 to a check node 160, denoted as 220 in FIG. 2B. Decoding an LDPC code is iterative: processing a variable node 150 once and processing a check node 160 once constitutes one iteration; thus the LDPC code is decoded by repeating these iterations until the processing converges (known as completion of the syndrome). The LLR information at the variable nodes 150 and check nodes 160 are updated after each iteration using known message-passing algorithms such as the min-sum algorithm and the sum-product algorithm. A posterior probability value, Pb, which is the LLR after an iteration process, is then determined by summing up the LLR information across all check nodes 160 connected to a variable node 150. Based on Pb, bit determination is performed to decide whether a bit in the decoded data received at a check node is either a ‘1’ or a ‘0’. This hard decision result is used to perform a parity check of the decoded LDPC code. When it is confirmed that no errors are present, the repetitive processing of the LDPC decoding is stopped.

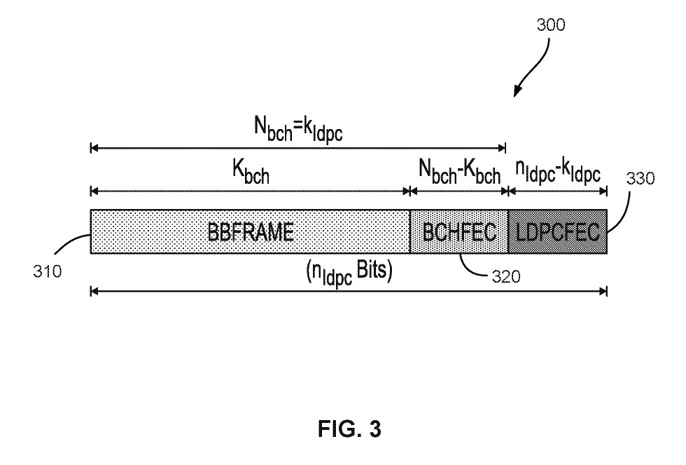

FIG. 3 shows the structure of user data encoded with a hard-decision parity scheme (such as a BCH code, for example) and a soft-decision parity scheme (such a LDPC code, for example) as is known in the art. As illustrated, the encoded data 300 comprises user data 310 appended with BCH parity bits 320 and LDPC parity bits 330. During decoding, all of the encoded data consisting of user data 300, BCH parity bits 320 and LDPC parity bits 330 is decoded by first decoding with an LDPC decoder, after which the (LDPC corrected) user data 300 and BCH parity bits is decoded using a BCH decoder. The BCH decoder is used to correct any residual bits in error which result from any mis-decoding by the LDPC decoder (which not guaranteed to converge on a correct solution, unlike a BCH decoder). As decoding the LDPC code is an iterative process involving probability calculations, decoding user data with large amounts of user data may require a large proportion of computation time and power which is highly inefficient.

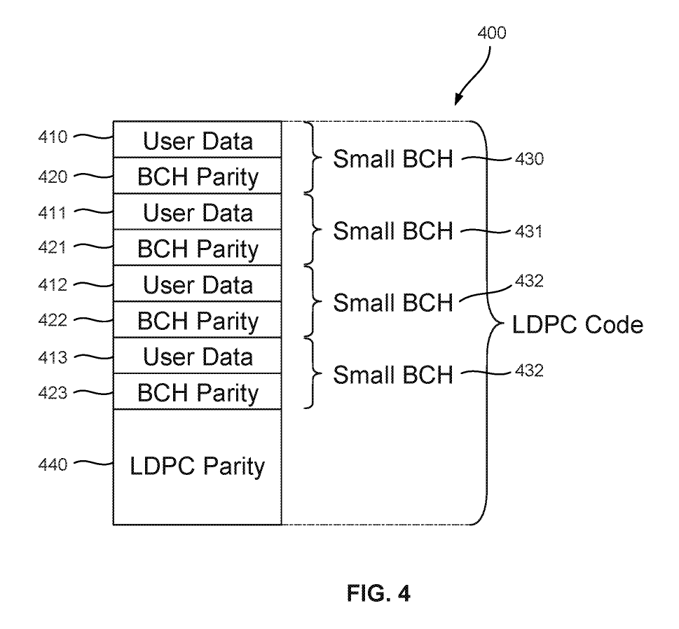

FIG. 4 illustrates the structure of user data 400 encoded with a hybrid soft-decision parity scheme (such as an LDPC code, for example) according to an implementation of the present disclosure. During encoding, the user data is split into a plurality of groups 410-413, and hard-decision parity bits 420-423 (such as an BCH parity bits, for example) are appended to each of the groups of user data groups 410-413. This results in several small BCH codes 430-433. LDPC parity bits 440 are then appended to the entire group of small BCH codes 430-433.

Comparing the structure of the encoded user data 400 with that in FIG. 3, it can be seen that the BCH code in the present disclosure has been split in accordance with the groups of user data 410-413. This size of this split is limited by a Hamming code, which is the smallest BCH code possible. There are several Hamming codes that can be applied to the user data, such as Single-Error Correcting (SEC) code and Single-Error Correcting Double-Error Detecting (SECDED) code. SEC codes correct one error in the decoded data, while SECDED codes correct one error and detect two errors. Optimum group sizes for SEC code are 127 and 255 bits, and optimum group sizes for BCH or SECDED code are 128 and 256 bits. The LDPC code 440, which is applied to the entire group of BCH or SEC/SECDED codes 430-433 spans the same number of bits as that used for the BCH or SEC/SECDED encoding. Splitting the BCH code of FIG. 3 in this manner into smaller BCH or SEC/SECDED codes increases efficiency as the amount of computational support required to algebraically hard decision decode the parity is minimized in accordance with the smaller group size 430-433.

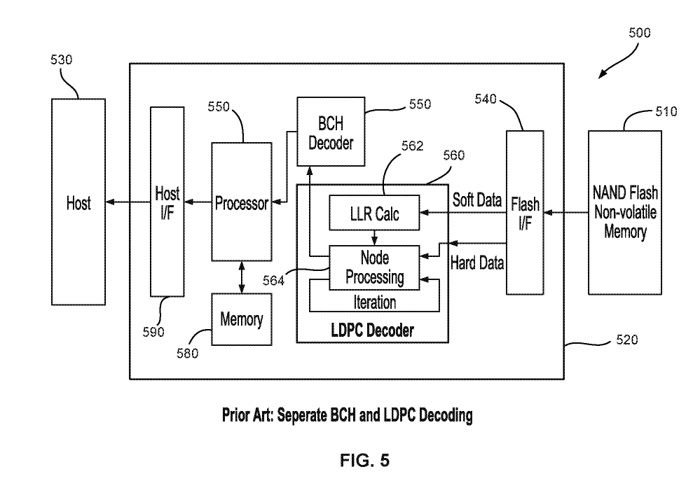

A prior art solid state storage device 500 and a control method for the solid state storage device 500 will now be described with reference to FIG. 5. The storage device 500 comprises a non-volatile memory 510, such as a NAND flash memory, for example, and a memory controller 520. The storage device 500 is connected to a host 530 such as a personal computer. The non-volatile memory 510 and the memory controller 520 may be mounted onto a memory card that is detachably connected with the host 530. The host 530 sends and requests data to and from the memory 510 via the memory controller 520.

The controller 520 comprises an interface unit 540, a hard-parity decoder 550, such as a BCH decoder, and a soft-parity decoder 560, such as an LDPC decoder. The NAND flash memory 510 is connected to the LDPC decoder 560 of the controller 520 via the interface unit 540. The LDPC decoder 560 comprises an LLR calculation module 562 and a node processing module 564. During a read operation, for example, soft read information from the NAND flash memory 510 (which may be derived from multiple reads of the memory cells using varying voltage thresholds for example) is fed into the LLR calculation module 562, and hard read information from the NAND flash memory 510 (ones and zeros from a single read of the memory cells for example) is fed into the node processing module 564 during a read operations. The LLR calculation module 562 is connected to the node processing module 564. The LLR calculation module 562 determines the LLR information relating to the variable and check nodes in the LDPC encoded data and transmits this information to the node processing module 564. The node processing module 564 decodes the LDPC codeword (such as codeword formed by the user data 310, the BCH parity bits 320, and the LDPC parity bits 330 in the data structure 300 in FIG. 3) until a solution is obtained. As previously mentioned this is an iterative process and the LDPC decoding continues until the solution converges to generate LDPC decoded data. For larger data units, decoding of the LDPC encoded data may be demanding on processing time and capacity.

The LDPC decoder 560 is coupled to the BCH decoder 550 and the LDPC decoded data from the node processing module 564 is input to the BCH decoder 550. The BCH decoder 550 is connected to the processor 570, which, in turn, is coupled to an embedded-type volatile memory 580 such as a Random Access Memory (RAM). The memory 580 may be configured to store startup data for the host, for example. The BCH decoder 550 decodes the BCH codeword (such as the codeword formed by 310+320 in the data structure 300 in FIG. 3) from the LDPC decoded data and relays the finally decoded data (such as the data frame 310 in the data structure 300 in FIG. 3) to the host device 530 via the processor 570 and the host interface 590.

As previously mentioned, this method of BCH decoding involves decoding the entire LDPC codeword from the read data in the first instance, which is an iterative and heavy on processing power as convergence of the soft-decision scheme is required to decode the required data. This can be especially inefficient for large data. After LDPC decoding, the BCH code is decoded to reveal the data requested by the host 530.

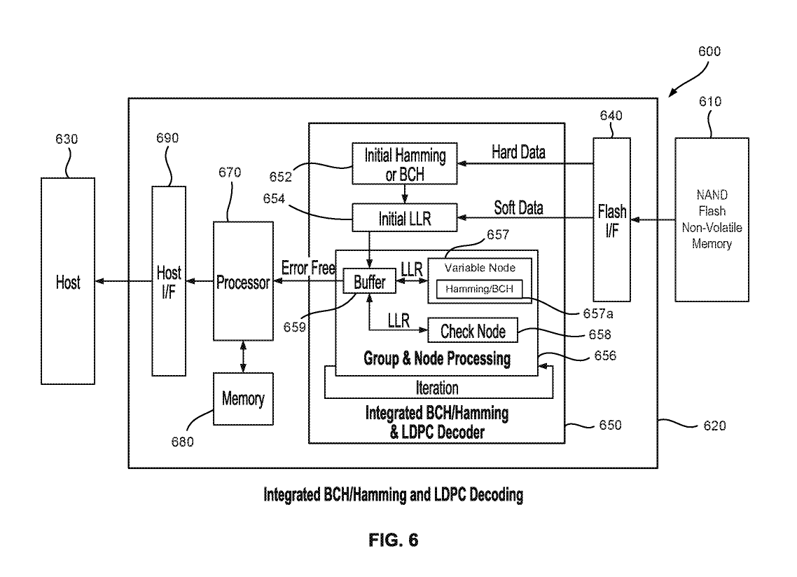

The present disclosure does away with this methodology and instead implements a hybrid BCH (SEC/SECDED) and LDPC decoding scheme which will be explained by reference to the solid state storage device 600 of FIG. 6. (Since a BCH code which corrects one, two or more errors (commonly referred to as t=1, t=2, t>2 . . . BCH codes) may be equivalently replaced by Hamming SEC or SECDED codes, we write BCH (SEC/SECDED) to mean any BCH t=1, t=2, t>2 . . . or Hamming SEC or Hamming SECDED code.)

The storage device 600 comprises a non-volatile memory 610 (e.g. NAND flash memory) and a memory controller 620. The memory 610 stores encoded data that takes the form as depicted in FIG. 4 in which the user data is split into a plurality of groups, and BCH (SEC/SECDED) parity bits are appended to each of the groups, after which LDPC parity bits are appended to the entire group of small BCH (SEC/SECDED) codes. Specifically, the outer code is split into many small BCH (SEC/SECDED) codes such that a large fraction of the parity in the encoded data is devoted to BCH (SEC/SECDED) codes as opposed to LDPC codes.

The storage device 600 is connected to a host 630. The non-volatile memory 610 and the memory controller 620 may be mounted onto a memory card that is detachably connected with the host 630. The host 630 writes and reads data to and from the memory 610 via the memory controller 620. The controller 620 comprises an interface unit 640, and an integrated BCH (SEC/SECDED) and LDPC decoder 650. The integrated decoder 650 is connected to a processor 670, which, in turn, is coupled to a volatile memory 680 such as a Random Access Memory (RAM), which may be configured to store startup data for the host 630, for example.

The integrated decoder 650 comprises an initial BCH (SEC/SECDED) decoder 652 that receives encoded data from the memory 610 via the interface 640. The integrated decoder 650 further includes an initial LLR module 654 that also receives the encoded data from the memory 610 via the interface 640. It should be noted that the encoded data from the memory 610 is received by the initial BCH (SEC/SECDED) decoder 652 and the initial LLR module 654 simultaneously such that information from the encoded data is made available to both the BCH (SEC/SECDED) decoder 652 and the LLR module 654 at the same time. The integrated decoder 650 also includes a group and node processing module 656 for decoding the LDPC code in the encoded data. The BCH (SEC/SECDED) decoder 652 decodes the BCH (SEC/SECDED) code in the encoded data received from the memory 610. This process does not drain the resources of the storage device 600 due to the multiple small BCH (SEC/SECDED) groups in the encoded data received from the memory 610. The BCH (SEC/SECDED) decoded data output from the BCH (SEC/SECDED) decoder 652 is fed into the initial LLR module 654, to which the BCH (SEC/SECDED) decoder 652 is coupled.

The LLR module 654 is connected to the group and node processing module 656. The LLR module 654 receives both the BCH (SEC/SECDED) decoded data from initial BCH (SEC/SECDED) decoder 652, and soft data from the memory 610 (which may be derived from multiple reads of the memory cells using different voltage thresholds for example), and determines the initial LLR information relating to the variable and check nodes in the encoded data. This initial LLR information is then relayed to the group and node processing module 656. The group and node processing module 656 comprises a variable node processing module 657, a check node processing module 658 and an LLR buffer 659. The variable node processing module 657 and the check node processing module 658 are each separately coupled to the LLR buffer 659. The variable node processing module 657 further comprises a BCH (SEC/SECDED) decoder 657a, which may be a soft decision Hamming decoder. The LLR buffer 659 is connected to the initial LLR module 654.

The LLR buffer 659 receives the initial LLR information from the LLR module 654 which has determined if the BCH (SEC/SECDED) decoded data from the BCH (SEC/SECDED) decoder 652 contains errors according to the following: The LLR module 654 generates the initial LLR value per input bit according to the output from the BCH (SEC/SECDED) decoder 652. If the BCH (SEC/SECDED) decoder 652 indicates that the decoded BCH (SEC/SECDED) code output from the BCH (SEC/SECDED) decoder 652 was error free, it assigns a first LLR value to the input bit. However if the BCH (SEC/SECDED) decoder 652 indicates a single error was present, the bit indicated by the error location has a second LLR value applied to the input bit. If the BCH (SEC/SECDED) decoder 652 indicates that the BCH (SEC/SECDED) code is unsolvable, a third LLR value is applied to the input bit. The first, second and third LLR values are pre-computed values. The LLR module 654 merges the LLR values applied by the LLR module 654 with additional soft information from the memory 610 to produce an improved LLR estimate for each bit in the BCH (SEC/SECDED) codeword. The LLR module 654 then uses this LLR estimate to determine if the decoded data from the BCH (SECDED) decoder 652 is error free. BCH SEC/SECDED decoded data with no errors are marked as very likely correct, and can then be excluded from further decoding by the group and node processing module 656. While decoded groups with apparently zero errors may be omitted from the iterated decoding within 656, there is a small possibility (<1 in 1,000) that a group is mis-decoded as having zero errors when in fact it has multiple errors. As a power saving first approximation these groups are first omitted from the iterative decoding. However, they may be included in a final phase of decoding along with the data groups that do contain errors as a final check for correctness which will check and correct for any mis-decoded groups with apparently zero errors. BCH (SEC/SECDED) decoded data with one error are fixed by the BCH (SECDED) decoder 657a within the variable node processing module 657.

Decoded data from the initial BCH (SECDED) decoder 652 with errors (including those with single errors as they may be mis-decodes) are decoded by the group and node processing module 656. Here the group and node processing module 656 decodes the LDPC code in the BCH (SEC/SECDED) decoded data containing multiple errors iteratively until a solution is obtained. As previously mentioned, the variable nodes send LLR information to the check nodes using a message passing algorithm, and the response messages from the check nodes are calculated using the min-sum LDPC decoding technique, for example, until the iterative decoding is complete.

The error free decoded data is then relayed to the host device 630 via the processor 670 and the host interface 690.

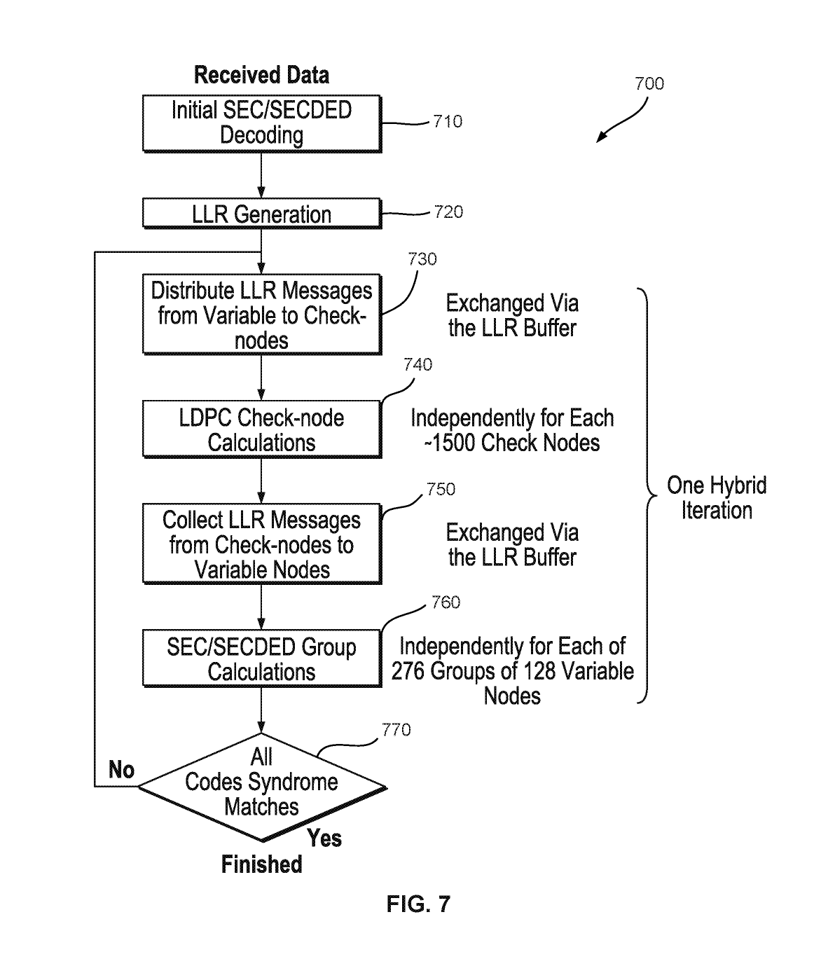

FIG. 7 illustrates a method 700 for decoding the data from a solid state device according to the hybrid LDPC-BCH (SEC/SECDED) decoding of the present disclosure, and will now be discussed with reference to the system block diagram of FIG. 6.

The method begins at step 710 in which the encoded data read from memory 610 is received by the initial BCH decoder 652 which decodes the BCH (SEC/SECDED) code in the data received from the memory 610. This decoding step makes use of the hard-decision parity data associated contained in the encoded data.

While shown as a subsequent step to step 710, step 720 is carried out in parallel with step 710. Here the LLR module 654 receives both the BCH (SEC/SECDED) decoded data from initial BCH (SEC/SECDED) decoder 652, and the soft data read information from the memory 610, and determines the initial LLR information relating to the variable and check nodes in the encoded data.

The method then progresses to step 730 in which the LLR buffer 659 receives the initial LLR information from the LLR module 654 and determines if the BCH (SEC/SECDED) decoded data from the BCH (SEC/SECDED) decoder 652 contains errors. BCH (SEC/SECDED) decoded data with no errors are marked as very likely correct, and are excluded from further decoding by the group and node processing module 656.

The LLR information for the remaining BCH (SEC/SECDED) decoded data is then distributed from variable to check nodes, as indicated in step 730. This relay of LLR information between variable and check nodes is as depicted in FIGS. 2A and 2B.

In step 740, the decoded data from the initial BCH (SEC/SECDED) decoder 652 with errors (one, two or more errors for SEC and SECDED codes) are decoded by the group and node processing module 656. Here the group and node processing module 656 decodes the LDPC code in the BCH (SEC/SECDED) decoded data containing multiple errors iteratively until a solution is obtained.

The LLR information from the various check and variable nodes is stored in the LLR buffer 659 so that it can be used by the variable node processing module 657 (and the BCH (SEC/SECDED) decoder 657a, if applicable) and the check node processing module 658. This is depicted in step 750 of FIG. 7.

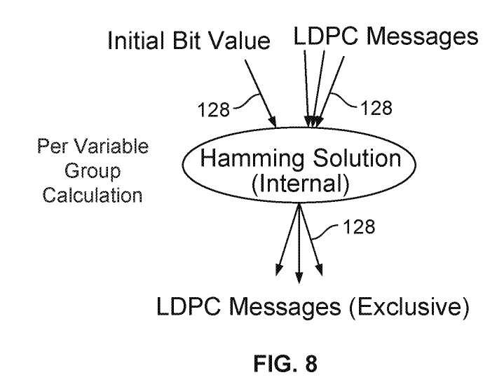

In step 760, SEC/SECDED decoded data with one error are fixed by the BCH decoder 657a within the variable node processing module 657. FIG. 8 illustrates this where the initial bit value of the BCH (SEC/SECDED) data and LDPC information is used during a Hamming solution decoding step per variable node group to give the decoded LDPC messages.

The method then progresses to decision step 770 where it is determined if all LDPC codes in the encoded data have been decoded. If there remains at least one LDPC code in the encoded data that has not been decoded, the method iterates to step 730 and steps 730 to 760 are repeated. If all LPDC codes in the embedded data has been decoded and error-free, the method ends and the error free decoded data is then relayed to the host device 630 via the processor 670 and the host interface 690.

Other objects, advantages and embodiments of the various aspects of the present invention will be apparent to those who are skilled in the field of the invention and are within the scope of the description and the accompanying Figures. For example, but without limitation, structural or functional elements might be rearranged consistent with the present invention. Similarly, principles according to the present invention could be applied to other examples, which, even if not specifically described here in detail, would nevertheless be within the scope of the present invention.

1. A solid state storage device, comprising:
a non-volatile memory configured to:
store further encoded data groups comprising a plurality of first encoded data groups collectively further encoded by a soft-decision parity scheme using a Low Density Parity Check (LDPC) code, each first encoded data group of the plurality being encoded using a hard decision parity scheme;
a non-volatile memory controller communicatively coupled to the non-volatile memory and configured to access the plurality of further encoded data groups; and
an integrated decoder, configured to:
decode the plurality of further encoded data groups to give first decoded data groups by hard-decision decoding the parity in each first encoded data group within the further encoded data groups;
generate log likelihood ratio (LLR) information to be associated with each of the first decoded data groups; and
iteratively further decode the first decoded data groups using the LLR information.

2. The solid state storage device of claim 1, further comprising:
a first decoder configured to decode the plurality of first encoded data groups within the further encoded data groups to generate the first decoded data groups;
an LLR module configured to receive the first decoded data groups and soft data derived from multiple reads of the non-volatile memory and generate LLR information; and
a processing module configured to iteratively decode the first decoded data groups using the LLR information.

3. The solid state storage device of claim 2, wherein the group and node processing module further comprises:
an LLR buffer configured to receive the LLR information from the LLR module, and wherein the LLR buffer is separately coupled to a variable node processing module and a check node processing module.

4. The solid state storage device of claim 3, wherein the variable node processing module further comprises a sub-decoder to decode the LLR information in the LLR buffer.

5. The solid state storage device of claim 4, wherein the sub-decoder is a hard-decision BCH decoder or a soft-decision Hamming code decoder.

6. The solid state storage device of claim 2, wherein the parity decoded by the first decoder is based on a BCH code or a Hamming code.

7. The solid state storage device of claim 1, wherein the hard-decision parity scheme is a single-error correcting (SEC) code or a single-error correcting double-error detecting (SECDED) code.

8. The solid state storage device of claim 7, wherein SEC or SECDED decoded data with one or more errors is fixed by the integrated decoder.

9. (canceled)

10. The solid state storage device of claim 8, wherein the integrated decoder independently uses LLR information as soft information in each iteration of decoding the parity.

11. (canceled)

12. (canceled)

13. A method of decoding non-volatile memory of a memory system, the method comprising:
accessing, by a non-volatile memory controller, data stored in the non-volatile memory, the data encoded into a plurality of first encoded data groups, each data group of the plurality being encoded using a first parity scheme;
accessing, by the non-volatile memory controller, a plurality of further encoded data groups, each of the plurality of further data groups being one of the plurality of first encoded data groups further encoded by a second parity scheme using a Low Density Parity Check (LDPC) code;
decoding, by the non-volatile memory controller, the plurality of first encoded data groups to give first decoded data groups by hard-decision decoding the first parity in each first encoded data group;
generating, by the non-volatile memory controller, log likelihood ratio (LLR) information to be associated with each of the first decoded data groups; and
iteratively further decoding the first decoded data groups using the LLR information.

14. The method of claim 13, wherein each iteration of the iterative decoding further comprises:
distributing, by a variable node processing module, the LLR information to a check node processing module;
storing the LLR information in an LLR buffer;
performing, by a check node processing module, LDPC check node calculations;
transferring, by the check node processing module, updated LLR information to a variable node processing module via the LLR buffer;
decoding, by a sub-decoder within the variable node processing module, the updated LLR information.

15. The method of claim 14, further comprising:
terminating the iterative decoding when the sub-decoder decodes the updated LLR information with no errors.

16. (canceled)

17. The method of claim 15, wherein the sub-decoder is a hard-decision BCH decoder or a soft-decision Hamming code decoder.

18. The method of claim 13, wherein the parity decoded by the non-volatile memory controller is a BCH code or a Hamming code.

19. The method of claim 13, wherein the first parity scheme is a single-error correcting (SEC) code or a single-error correcting double-error detecting (SECDED) code.

20. (canceled)

21. (canceled)

22. (canceled)

23. (canceled)

24. (canceled)

25. The solid state storage device of claim 3, wherein the LLR module is configured to assign LLR values to the first decoded data groups according to whether the decoded output of the first decoder contains no errors or contains one error, or whether the first decoder does not converge to a solution.

26. The solid state storage device of claim 25, wherein the LLR information in the LLR buffer is decoded by the group and node processing module.

27. The solid state storage device of claim 26, wherein the iterative decoding by the group and node processing module is performed iteratively using soft decision decoding until an error free solution is obtained.
